(19) United States
(12) Patent Application Publication
(10) Pub. No.: US 2009/0121323 A1
(43) Pub. Date: May 14, 2009

(54) SEMICONDUCTOR DEVICE AND METHOD OF FABRICATING THE SAME

(75) Inventors: Yong-Chai KWON, Suwon-si (KR); Nam-Seong KIM, Yongin-si (KR)

Correspondence Address: STANZIONE & KIM, LLP, 919 18TH STREET, N.W., SUITE 440, WASHINGTON, DC, 20006, US

(73) Assignee: Samsung Electronics Co., Ltd, Suwon-si (KR)

(21) Appl. No.: 12/266,748

(22) Filed: Nov. 7, 2008

(30) Foreign Application Priority Data
Nov. 8, 2007 (KR) 2007-113799

(51) Int. Cl. H01L 23/48

(52) U.S. Cl. 257/621; 257/E23.011

(57) ABSTRACT

A semiconductor device and a method of fabricating the same. The semiconductor device includes a semiconductor substrate including an active surface and an inactive surface which faces the active surface, a device isolation layer and a pad stacked on the active surface; and a through electrode disposed in a first via hole and a second via hole and including a protruding part that protrudes from the pad, the first via hole penetrating the semiconductor substrate, the second via hole penetrating the device insulation layer and the pad continuously, wherein at least a surface of the protruding part of the through electrode is formed of an oxidation resistance-conductive material.

### CROSS-REFERENCE TO RELATED APPLICATIONS

This U.S. non-provisional patent application claims priority under 35 U.S.C. § 119 from Korean Patent Application No. 10-2007-0113799, filed on Nov. 8, 2007, the disclosure of which is incorporated herein in its entirety by reference.

### BACKGROUND

1. Field of the Invention

The present general inventive concept relates to a semiconductor device and a method of fabricating the same, and more particularly, to a stackable semiconductor device, and a method of fabricating the same.

2. Description of the Related Art

Since a semiconductor industry has been highly developed, demands for low weight, miniaturized, and high speed semiconductor products have steadily increased. In addition to that, demands for multi-functional semiconductor products which are used for multiple functions have also gradually increased. In order to meet these demands, a method of further reducing a size, a minimum weight, a width of a semiconductor pattern and/or a method of fabricating other kinds of semiconductor devices into one semiconductor device have been suggested.

Recently, an example of a method for satisfying the above demands for a semiconductor product, a packaging technique for three-dimensionally stackable semiconductor devices has attracted the attention of the semiconductor industry. By stacking the same or different types of semiconductor devices, a low weight, multi-function, miniaturized and/or high speed semiconductor product can be achieved.

Terminals of stacked semiconductor devices are electrically connected to each other through a wire bonding technology. However, a typical wire bonding technology faces various limitations. For example, since a certain amount of space is required for wire bonding, miniaturization of a semiconductor product is limited thereby. Additionally, signal delay due to a wire length occurs such that a high operating speed of a semiconductor product is also limited. Furthermore, all of the terminals of the stacked semiconductor devices must be exposed for wire bonding. Accordingly, a bottom semiconductor device must have a larger size than that of a top semiconductor device. As a result, manufacturing processes of a semiconductor product becomes complex and the miniaturization of the semiconductor product also becomes limited.

However, techniques for stacking semiconductor devices that do not require wires are actively under development in order to resolve the technical limitations of the above wire bonding processes. In one example, a method of interposing a bump between a terminal (hereinafter, referred to as a bottom terminal) of a bottom semiconductor device and a terminal (hereinafter, referred to as a top terminal) of a top semiconductor device has been suggested. In relation to the above method, the stacking of the semiconductor devices includes forming a bump on a bottom terminal and stacking the bottom and top semiconductor devices by aligning a top terminal to the bump. However, there exists various limitations in this case. For example, the bump must be aligned on the bottom terminal, and then the top terminal needs to be aligned with the bump. That is, two separate alignment processes are required for stacking the bottom and top semiconductor devices. Accordingly, a reliability of the stacked semiconductor devices may be deteriorated. Furthermore, a total thickness of the stacked semiconductor devices increases due to the bump.

Furthermore, terminals and/or bumps of a semiconductor device, made of copper or aluminum, oxidize easily. Therefore, in order to remove a natural oxide layer formed on the surfaces of terminals and/or bumps, flux must be applied on the bottom semiconductor device before stacking the top semiconductor device. Additionally, after stacking and bonding the top semiconductor device on the flux-applied bottom semiconductor device, an additional process of removing the remaining flux is required. As a result, because the additional processes for applying and removing the flux are necessary, a productivity of the semiconductor product is substantially reduced. Additionally, the remaining flux may not be completely removed during the flux removal process. For that reason, the reliability of a semiconductor product further deteriorates.

### SUMMARY

Additional aspects and/or utilities of the present general inventive concept will be set forth in part in the description which follows and, in part, will be obvious from the description, or may be learned by practice of the general inventive concept.

The foregoing and/or other aspects and utilities of the present general inventive concept may be achieved by providing semiconductor devices which include a semiconductor substrate including an active surface and an inactive surface facing one another, a device isolation layer and a pad sequentially stacked on the active surface, and a through electrode disposed in a first via hole and a second via hole and including a protruding part that protrudes from the pad, the first via hole penetrating the semiconductor substrate, the second via hole penetrating the device insulation layer and the pad continuously, wherein at least a surface of the protruding part of the through electrode is formed of an oxidation resistance-conductive material.

In exemplary embodiments, the through electrode may include an external pattern formed of the oxidation resistance-conductive material and an internal pattern disposed in a concave region defined by the external pattern, wherein the concave region may include an open entrance at the inactive surface and the oxidation resistance-conductive material may include a higher oxidation resistance than the internal pattern.

In other exemplary embodiments, the internal pattern may be formed of a low melting point conductive material having a lower melting point than that of the external pattern.

In still other exemplary embodiments, the concave region may be defined in the first and second via holes and the protruding part.

In even other exemplary embodiments, the internal pattern may completely fill the concave region.

In yet other exemplary embodiments, the internal pattern may fill the concave region in the protruding part and the second via hole, and also may correspond to a profile of the concave region in the first via hole.

In further exemplary embodiments, the protruding part is formed of the external pattern, the external pattern may fill the second via hole, and the concave region may be defined in the first via hole.

In still further exemplary embodiments, the internal pattern may completely fill the concave region.

In even further exemplary embodiments, the internal pattern may correspond to a profile of the concave region.

In yet further exemplary embodiments, the through electrode may further include an interlayer conductive pattern disposed between the internal pattern and the external pattern, the interlayer conductive pattern including at least one of an adhesive conductive material and a barrier conductive material.

In yet further exemplary embodiments, the through electrode may be entirely formed of the oxidation resistance-conductive material, may fill the second via hole, and may correspond to a profile of the first via hole, thereby defining a mounting recessed region surrounded by the through electrode in the first via hole.

In yet further exemplary embodiments, the oxidation resistance-conductive material may be formed of a precious metal.

In yet further exemplary embodiments, the through electrode may include a mounting region in the first via hole, where a protruding type terminal of another semiconductor may be capable of being mounted.

In yet further exemplary embodiments, the semiconductor devices may further include a barrier insulation layer disposed between a sidewall of the first via hole and the through electrode.

In yet further exemplary embodiments, a width of the protruding part may be less than that of the first via hole.

The foregoing and/or other aspects and utilities of the present general inventive concept may also be achieved by providing methods of fabricating a semiconductor device which include preparing a semiconductor structure with a semiconductor substrate, a device isolation layer, and a pad, the semiconductor substrate having an active surface and an inactive surface facing one another, the device insulation layer and the pad being sequentially stacked on the active surface, patterning the semiconductor substrate from the inactive surface toward the active surface to form a first via hole, forming a second via hole connected to the first via hole and continuously penetrating the device insulation layer and the pad, and forming a through electrode disposed in the first and second via holes and including a protruding part that protrudes from the pad.

In exemplary embodiments, before the forming of the first via hole, the methods may further include forming a substrate adhesive layer on the pad and the device insulation layer and bonding a support substrate on the substrate adhesive layer, wherein the forming of the second via hole includes patterning the device insulation layer, the pad, and the substrate adhesive layer.

In other exemplary embodiments, before the forming of the second via hole, the methods may further include conformally forming a barrier insulation layer in the first via hole, wherein the forming of the second via hole includes patterning the barrier insulation layer, the device insulation layer, the pad, and the substrate adhesive layer.

In still other exemplary embodiments, the forming of the through electrode may include forming an external pattern in the first and second via holes and forming an internal pattern in a concave region surrounded by the external pattern, wherein the external pattern is formed of a conductive material having a higher oxidation resistance than that of the internal pattern, and the internal pattern is formed of a conductive material having a lower melting point than that of the external pattern.

In even other exemplary embodiments, the through electrode may be entirely formed of an oxidation resistance-conductive material and a mounting recessed region surrounded by the through electrode is defined in the first via hole.

The foregoing and/or other aspects and utilities of the present general inventive concept may also be achieved by providing an electronic system which includes a semiconductor substrate having a first side and a second side, an insulation layer disposed on the first side and capable of having circuits and/or components disposed therein, and a through electrode disposed within the semiconductor to provide electrical communication between the first side, the second side, and the insulation layer.

### BRIEF DESCRIPTION OF THE DRAWINGS

These and/or other aspects and utilities of the present general inventive concept will become apparent and more readily appreciated from the following description of the exemplary embodiments, taken in conjunction with the accompanying drawings of which:

FIG. 1 is a cross-sectional schematic view of a semiconductor device according to an exemplary embodiment of the present general inventive concept;

FIG. 2 is a cross-sectional schematic view illustrating one modification of a semiconductor device according to the embodiment of FIG. 1;

FIG. 3 is a cross-sectional schematic view illustrating another modification of a semiconductor device according to the embodiment of FIG. 1;

FIG. 4 is a cross-sectional schematic view illustrating another modification of a semiconductor device according to the embodiment of FIG. 1;

FIG. 5 is a cross-sectional schematic view illustrating a semiconductor package with a semiconductor device according to the embodiment of FIG. 1;

FIGS. 6 through 12 are cross-sectional schematic views illustrating a method of forming a semiconductor device according to exemplary embodiments of the present general inventive concept;

FIGS. 13 and 14 are cross-sectional schematic views illustrating one modification of a method of forming a semiconductor device according to the embodiments of FIGS. 6 through 12;

FIG. 15 is a cross-sectional schematic view of a semiconductor device according to another exemplary embodiment of the present general inventive concept; and

FIG. 16 is a cross-sectional view of a semiconductor device according to another exemplary embodiment of the present general inventive concept.

### DETAILED DESCRIPTION OF THE PREFERRED EMBODIMENTS

Preferred exemplary embodiments of the present general inventive concept will be described below in more detail with reference to the accompanying drawings. The present general inventive concept may, however, be embodied in different forms and should not be construed as limited to the exemplary embodiments set forth herein. Rather, these exemplary embodiments are provided so that this disclosure will be thorough and complete, and will fully convey the scope of the present general inventive concept to those skilled in the art. In the drawings, the thickness of a layer (or film) and regions are exaggerated for clarity. It will also be understood that when a layer (or film) is referred to as being ‘on’ another layer or substrate, it can be directly on the other layer or substrate, or intervening layers may also be present. Also, it will be understood that when a layer is referred to as being “formed on” another layer or substrate, it may also be “disposed on” the other layer or substrate. Further, it will be understood that when a layer is referred to as being ‘under’ another layer, it can be directly under, and one or more intervening layers may also be present. Like reference numerals refer to like elements throughout.

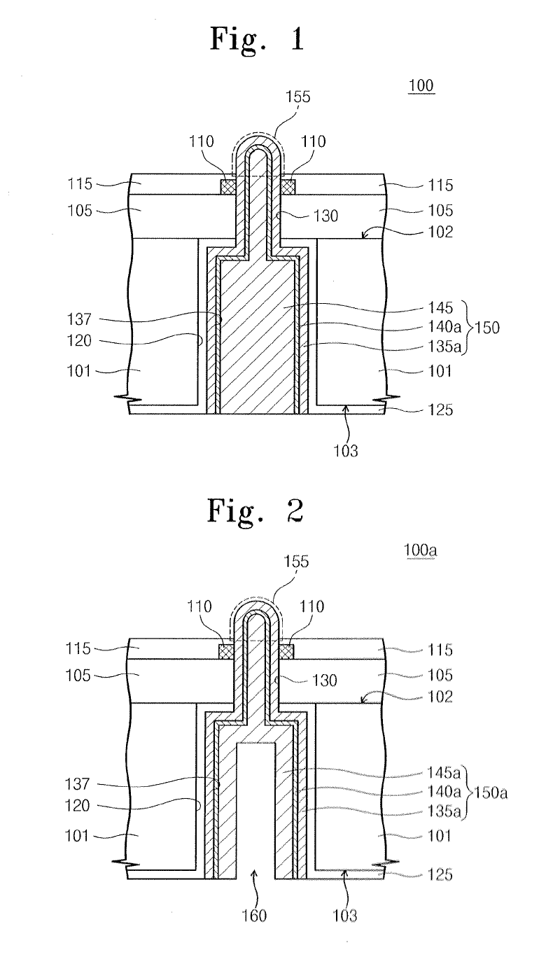

FIG. 1 is a cross-sectional schematic view of a semiconductor device according to an exemplary embodiment of the present general inventive concept. Referring to FIG. 1, a semiconductor device 100 according to an exemplary embodiment of the present general inventive concept includes a semiconductor substrate 101, a device isolation layer 105, and a pad 110. In exemplary embodiments, the semiconductor substrate 101 includes an active surface 102 and an inactive surface 103, which faces the active surface 102. In exemplary embodiments, the device isolation layer 105 and the pad 110 may be sequentially stacked on the active surface 102. The pad 110 may be disposed on a predetermined region of the device isolation layer 105. Semiconductor components (not illustrated), which the semiconductor device 100 require, may be disposed on the active surface 102 and in the device isolation layer 105. In an exemplary embodiment, if the semiconductor device 100 is a logic device, a logic circuit may be disposed on the active surface 102 and in the device isolation layer 105. However, in alternative exemplary embodiments, memory cells, a peripheral circuit to control the memory cells, and wirings to mutually connect the memory cells and the peripheral circuit may be disposed on the active surface 102 and in the device insulation layer 105, if the semiconductor device 100 is a memory device. In further exemplary embodiments, the device isolation layer 105 may include a plurality of insulation layers. In an exemplary embodiment, the pad 110 may correspond with an input/output terminal which inputs/outputs a signal between the semiconductor device 100 and external devices (not illustrated).

In exemplary embodiments, a protective insulation layer 115 may cover at least a portion of the pad 110 and the device insulation layer 105. In further exemplary embodiments, the wirings (not illustrated) formed of a same conductive material as the pad 110 may be laterally spaced apart from the pad 110 on the device insulation layer 105. At this point, the protective insulation layer 115 laterally covers the wirings which are spaced apart from the pad 110. In exemplary embodiments, the wirings may provide electrical communication between circuits and/or electrical components disposed on or within device insulation layer 105 and external devices (not illustrated) through the pad 110. In further exemplary embodiments, the protective insulation layer 115 may protect the semiconductor device 100 from an external stress (e.g., pressure) and/or moisture. However, the present general inventive concept is not limited thereto. That is, the protective layer 115 may also protect the semiconductor device 100 from various other stresses, such as an internal stress. Additionally, in exemplary embodiments, the protective insulation layer 115 may be used to prevent unnecessary electrical contact between the semiconductor device 100 and another semiconductor device or a package substrate. In an exemplary embodiment, the protective insulation layer 115 may include at least one selected from a polymer, an oxide layer, and a nitride layer. According to the present exemplary embodiment, the protective insulation layer 115 may be omitted.

A first via hole 120 penetrates the semiconductor substrate 101 from the inactive surface 102 toward the active surface 103. A second via hole 130 penetrates through the device insulation layer 105 and the pad 110. In the present exemplary embodiment, the second via hole 130 is connected to the first via hole 120. In exemplary embodiments, the first via hole 120 and the second via hole 130 may be stacked in a direction substantially vertical to the active surface 102.

In exemplary embodiments, a through electrode 150 is disposed in the first and second via holes 120 and 130, and includes a protruding part 155 which protrudes from the pad 110. In the present exemplary embodiment, at least one surface of the protruding part 155 of the through electrode 150 may be formed of an oxidation resistance-conductive material. In exemplary embodiments, the through electrode 150 may be electrically connected to the pad 105. In an exemplary embodiment, the through electrode 150 contacts a side of the pad 110 which is exposed to a sidewall of the second via hole 130. However, the present general inventive concept is not limited thereto. That is, in alternative exemplary embodiments, the through electrode 150 may contact other portions of the pad 110. As illustrated in the drawings, in exemplary embodiments, the through electrode 150 may fill the first and second via holes 120 and 130 (see FIGS. 1 and 2). In the present exemplary embodiment, a surface of the through electrode 150, which is adjacent to the inactive surface 103, may be substantially planar to the inactive surface 103 (see FIG. 1).

In exemplary embodiments, a width of the second via hole 130 may be equal to or less than that of the first via hole 120. However, the present general inventive concept is not limited thereto. In exemplary embodiments, the protruding part 155 may include a sidewall which is aligned to the sidewall of the second via hole 130. Accordingly, in exemplary embodiments, the protruding part 155 may include a smaller width than that of the first via hole 120.

In exemplary embodiments, the protruding part 155 may contact a terminal of another semiconductor device or a package substrate (e.g., a printed circuit board for package). In exemplary embodiments, the protruding part 155 may be mounted in a terminal of the other semiconductor device or package substrate. In exemplary embodiments, the protruding part 155 may protrude beyond a surface of the protective insulation layer 115. In exemplary embodiments, if the protective insulation layer 115 completely covers the pad 110, the protruding part 155 may penetrate the protective insulation layer 115 and may also protrude beyond a surface of the protective insulation layer 115. In further exemplary embodiments, the protective insulation layer 115 may include an opening part that exposes the pad 110. In the present exemplary embodiment, the protruding part 155 protrudes beyond a surface of the protective insulation layer 115 through an opening part of the protective insulation layer 115. However, the present general inventive concept is not limited thereto. That is, in alternative exemplary embodiments, the protruding part 155 may be flush to or below a surface of the protective insulation layer 115.

In exemplary embodiments, the through electrode 150 may include an external pattern 135a and an internal pattern 145. In the present exemplary embodiment, the external pattern 135a may be formed of an oxidation resistance-conductive material. In an exemplary embodiment, the external pattern 135a may be formed of an oxidation resistance-conductive material having a higher oxidation resistance than that of the internal pattern 145. In further exemplary embodiments, the internal pattern 145 may be formed of a low melting point conductive material having a lower melting point than that of the external pattern 135a. In yet further exemplary embodiments, the internal pattern 145 may be formed of solder or tin. In yet further exemplary embodiments, the external pattern 135a may be formed of a precious metal (e.g., Au, Pd, Ag, Ru, and Pt). However, the present general inventive concept is not limited thereto. That is, the internal and external pattern 145, 135a may be formed of various other materials known in the art.

In exemplary embodiments, the external pattern 135a may define a concave region 137 in the first and second via holes 120 and 130 and the protruding part 155. In further exemplary embodiments, the concave region 137 may have an open entrance at the inactive surface 103. That is, the concave region 137 may be substantially surrounded by the external pattern 135a having a uniform thickness and may correspond to a space disposed in the first and second via holes 120 and 130 and around the protruding part 155. In exemplary embodiments, the internal pattern 145 may be disposed in the concave region 137. As illustrated in the drawings, in exemplary embodiments, the internal pattern 145 may fill the concave region 137. Accordingly, the protruding part 155 may include a portion of the internal pattern 145 and a portion of the external pattern 135a surrounding the portion of the internal pattern 145. In an exemplary embodiment, the external pattern 135a may contact the pad 110.

In exemplary embodiments, the through electrode 150 may further include an interlayer conductive pattern 140a interposed between the internal pattern 145 and the external pattern 135a. The interlayer conductive pattern 140a may include at least one among an adhesion conductive material and a barrier conductive material. The adhesion conductive material may be a conductive material capable of improving an adhesion between the internal pattern 145 and the external pattern 135a. In an exemplary embodiment, the adhesion conductive material may include at least one material of titanium, tantalum, and nickel. However, the present general inventive concept is not limited thereto. That is, the adhesion conductive material may also include various other materials known in the art. In exemplary embodiments, the barrier conductive material may be a conductive material capable of preventing atom diffusion between the internal pattern 145 and the external pattern 135a. In an exemplary embodiment, the barrier conductive material may be a conductive metal nitride (e.g., nitride titanium or nitride tantalum). However, the present general inventive concept is not limited thereto.

In exemplary embodiments, a barrier insulation layer 125 may be disposed between the through electrode 150 and a sidewall of the first via hole 120. In an exemplary embodiment, the barrier insulation layer 125 may be conformally disposed along the device insulation layer 105 which is exposed by the first via hole 120 and the sidewall of the first via hole 120. In further exemplary embodiments, the barrier insulation layer 125 may be formed to correspond to a shape of the first via hole 120. In the present exemplary embodiment, the second via hole 130 extends to penetrate through the barrier insulation layer 125. In exemplary embodiments, the through electrode 150 and the semiconductor substrate 101 may be spaced apart from each other by the barrier insulation layer 125. Additionally, in exemplary embodiments, atoms in the through electrode 150 may be prevented from diffusing into the semiconductor substrate 301 through the barrier insulation layer 125. In exemplary embodiments, the barrier insulation layer 125 extends to cover at least a portion of the inactive surface 103 of the semiconductor substrate 101. In exemplary embodiments, the barrier insulation layer 125 may include at least one of a polymer, an oxide layer, a nitride layer, and a parylene. However, the present general inventive concept is not limited thereto. That is, the barrier insulation layer 125 may include various other materials known in the art.

In exemplary embodiments, the through electrode 150 may include a mounting region in the first via hole 120 where a protruding type terminal of another semiconductor device may be combined. In an exemplary embodiment, when the other semiconductor device is combined on the inactive surface 103, a protruding type terminal of other semiconductor device may be combined on the mounting region in the first via hole 120. That is, the protruding type terminal may be disposed in the first via hole 120 and may contact the through electrode 150. In exemplary embodiments, the mounting region of the semiconductor device 100 may be filled with the internal pattern 145, which is formed of a low melting point conductive material. In the present exemplary embodiment, the protruding type terminal of other semiconductor device may have a higher melting point than that of the internal pattern 145. Furthermore, the protruding type terminal of the other semiconductor device may be formed of an oxidation resistance-conductive material. In an exemplary embodiment, the protruding type terminal of the other semiconductor device may be formed of at least one of the conductive materials used for the forming the external pattern 135a.

In the semiconductor device 100, the internal pattern 145 completely fills the concave region 137. However, in alternative exemplary embodiments, the internal pattern 145 may fill a portion of the concave region 137. This will now be described in more detail with reference to FIG. 2.

FIG. 2 is a cross-sectional schematic view which illustrates one modification of a semiconductor device according to an exemplary embodiment of the present general inventive concept.

Referring to FIG. 2, a semiconductor device 100a includes a through electrode 150a. In exemplary embodiments, the through electrode 150a may be disposed in a first via hole 120 which penetrates the semiconductor substrate 101 and in a second via hole 130 which penetrates a device insulation layer 105 and a pad 110. Additionally, the through electrode 150a may include a protruding part 155 which protrudes from the pad 110. In exemplary embodiments, the through electrode 150a may include an external pattern 135a and an internal pattern 145a. In further exemplary embodiments, the external pattern 135a may define a concave region 137 having an open entrance at the inactive surface 103, and the internal pattern 145a may be disposed in the concave region 137. In an exemplary embodiment, the internal pattern 145a may fill the protruding part 155 and the concave region 137 of the internal pattern 145a. However, in alternative exemplary embodiments, the internal pattern 145a may substantially extend with a uniform thickness along the sidewall of the concave region 137 in the first via hole 130. That is, the internal pattern 145a may fill a portion of the concave region 137 in the first via hole 120. In exemplary embodiments, a mounting recessed region 160 which is surrounded by the internal pattern 145a may be defined in the first via hole 120. In an exemplary embodiment, the mounting recessed region 160 may correspond to a space which is surrounded by the internal pattern 145a displaced in the first via hole 120.

In exemplary embodiments, the through electrode 150a includes a mounting region where a protruding type terminal of another semiconductor may be mounted. In the present exemplary embodiment, the mounting region of the through electrode 150a includes at least a portion of the internal pattern 145a in the first via hole 120 and in a portion of the mounting recessed region 160. In an exemplary embodiment, the internal pattern 145a is formed of a same or substantially similar material as the internal pattern 145 of FIG. 1. That is, the external pattern 135a may be formed of an oxidation resistance-conductive material having a higher oxidation resistance than that of the internal pattern 145a, and the internal pattern 145a may be formed of a low melting point conductive material having a lower melting point than that of the external pattern 135a. In exemplary embodiments, the through electrode 150a may further include an interlayer conductive pattern 140a interposed between the internal and external patterns 145a and 135a. In order to avoid redundancy, an overlapping description for the interlayer conductive pattern 140a as described above will be omitted.

On the other hand, in exemplary embodiments, according to the semiconductor devices 100 and 100a of FIGS. 1 and 2, the concave region 137 may be defined in the first via hole 120, in the second via hole 130, and in the protruding part 155. However, in alternative exemplary embodiments, the concave region which is defined by the external pattern may be disposed in and being limited by the first via hole 120. These exemplary embodiments will now be described in more detail with reference to the drawings.

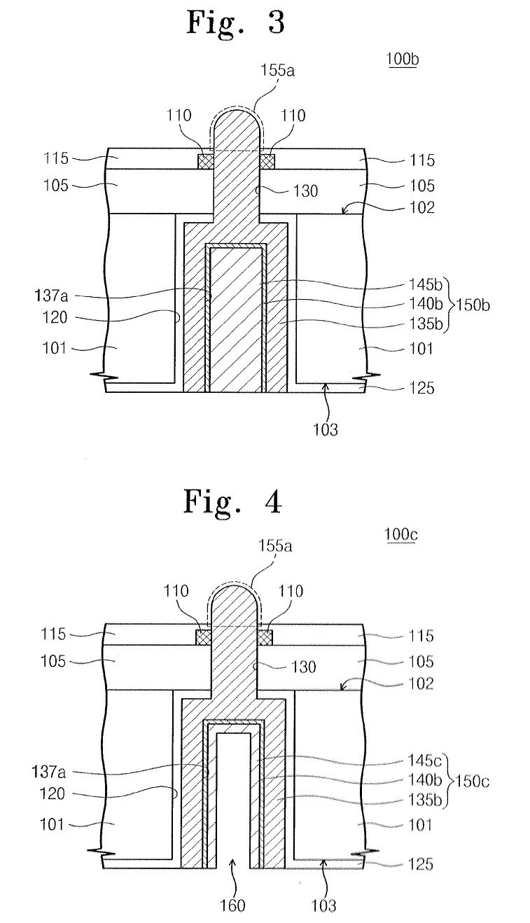

FIG. 3 is a cross-sectional schematic view which illustrates another modification of a semiconductor device according to an exemplary embodiment of the present general inventive concept.

Referring to FIG. 3, a semiconductor device 100b includes a through electrode 150b. In exemplary embodiments, the through electrode 150b may be disposed in a first via hole 120 which penetrates the semiconductor substrate 101 and in a second via hole which penetrates a device insulation layer 105 and a pad 110. Additionally, the through electrode 150b may include a protruding part 155a which protrudes from the pad 110. However, the present general inventive concept is not limited thereto. That is, in alternative exemplary embodiments, the through electrode 150b may be flush to or beneath a surface of the pad 110.

The through electrode 150b includes an external pattern 135b and an internal pattern 145b. In exemplary embodiments, the external pattern 135b may define a concave region 137a having an open entrance at an inactive surface 103. In the present exemplary embodiment, the concave region 137a may be disposed in and being limited by the first via hole 120. In exemplary embodiments, the protruding part 137a may be formed entirely of the external pattern 135b, and the external pattern 135b may fill the second via hole 130. In further exemplary embodiments, the external pattern 135b may extend along the sidewall of the first via hole 120 to define the concave region 137a in the first via hole 120. In an exemplary embodiment, the internal pattern 145b may fill the concave region 137a. However, the present general inventive concept is not limited thereto.

In exemplary embodiments, the external pattern 135b may be formed of an oxidation resistance-conductive material having a higher oxidation resistance than that of the internal pattern 145b. In further exemplary embodiments, the internal pattern 145b may be formed of a low melting conductive material having a lower melting point than that of the external pattern 135b. In yet further exemplary embodiments, the external pattern 135b and the internal pattern 145b may be formed of the same or substantially similar materials as the external pattern 135a and the internal pattern 145, respectively.

In exemplary embodiments, a mounting region of the through electrode 150b where a protruding type terminal of another semiconductor device may be mounted is filled by the internal pattern 145b. In exemplary embodiments, the through electrode 150b may further include an interlayer conductive pattern 140b interposed between the internal pattern 145b and the external pattern 135b. In the present exemplary embodiment, the interlayer conductive pattern 140b may be formed of the same or substantially similar material as the interlayer conductive pattern 140a of FIG. 1.

FIG. 4 is a cross-sectional schematic view which illustrates another modification of a semiconductor device according to an exemplary embodiment of the present general inventive concept.

Referring to FIG. 4, a semiconductor device 100c includes a through electrode 150c. In exemplary embodiments, the through electrode 150c may be disposed in a first via hole 120 and in a second via hole 130, and may also include a protruding part 155a which protrudes from a pad 110. The through electrode 150c includes an external pad 135b and an internal pattern 145c. In exemplary embodiments, the external pattern 135b may define a concave region 137a within the first via hole 120, and the internal pattern 145c may be disposed within the concave region 137a. In the present exemplary embodiment, the internal pattern 145c may be conformally disposed along the internal surface of the concave region 137a. Therefore, a mounting recessed region 160, which is surrounded by the internal pattern 145c, may be defined in the first via hole 120. In exemplary embodiments, the internal pattern 145c may be disposed to correspond to a shape of the first via hole 120.

In further exemplary embodiments, the through electrode 150c includes a mounting region in the first via hole 120 where a protruding type terminal of another semiconductor device (not illustrated) may be mounted. In exemplary embodiments, the mounting region of the through electrode 150c includes at least a portion of the internal pattern 145c and at least a portion of the mounting recessed region 160. In further exemplary embodiments, the external pattern 135b and the internal pattern 145c may be formed of the same or substantially similar materials as the external pattern 135b and the internal pattern 145b, respectively, of FIG. 3.

Next, a semiconductor package including semiconductor devices according to an exemplary embodiment of the present general inventive concept will now be described in more detail with reference to the accompanying drawings.

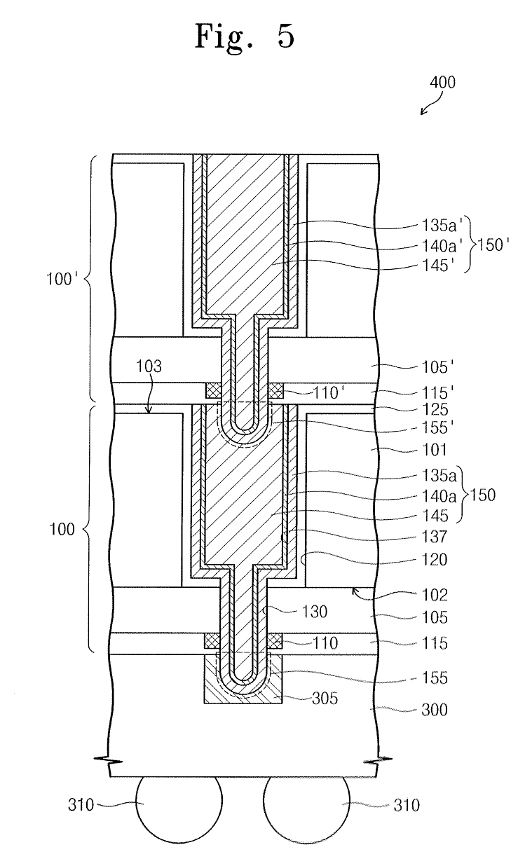

FIG. 5 is a cross-sectional schematic view which illustrates a semiconductor package including a semiconductor device according to an exemplary embodiment of the present general inventive concept.

Referring to FIG. 5, a semiconductor package 400 includes a package substrate 300 and a plurality of stacked semiconductor devices 100 and 100′ disposed on the package substrate 300. According to the present exemplary embodiment, the first semiconductor device 100 and the second semiconductor device 100′ may be disposed on the package substrate 300. However, the present general inventive concept is not limited thereto. That is, in exemplary embodiments, two or more semiconductor devices may be stacked on the package substrate 300. However, in alternative exemplary embodiments, one device selected from the semiconductor devices 100, 100a, 100b, and 100c of FIGS. 1 through 4 may be stacked on the package substrate 300. In exemplary embodiments, the package substrate 300 may be a chip sized printed circuit board. In further exemplary embodiments, the semiconductor devices 100 and 100′, which are stacked on the package substrate 300, may be protected through a molding material (not illustrated).

In the present exemplary embodiment, the first semiconductor device 100 is substantially similar to the semiconductor device 100 of FIG. 1. In exemplary embodiments, the package substrate 300 may include an internal terminal 305 and an external terminal 310. In further exemplary embodiments, the internal terminal 305 may be connected to a protruding part 155 of a through electrode 150 in the first semiconductor device 100. However, the present general inventive concept is not limited thereto. That is, the internal terminal 305 and the protruding part 155 may be directly or indirectly connected such that there exists an electrical communication therebetween. In further exemplary embodiments, the external terminal 310 may be connected to an external device (not illustrated). In yet further exemplary embodiments, the internal terminal 305 may be formed of a low melting point conductive material having a lower melting point than that of a conductive material for the surface of the protruding part 155 of the first semiconductor device 100. The protruding part 155 of the first semiconductor device 100 may be mounted in the internal pad 305. In further exemplary embodiments, the external terminal 310 may be in a ball shape. However, the present general inventive concept is not limited thereto. That is, the external terminal 310 may be formed in various other shapes, as desired.

As mentioned above, in exemplary embodiments, at least one surface of the protruding part 155 of the first semiconductor device 100 may be formed of an oxidation resistance-conductive material. Therefore, in the present exemplary embodiment, the forming of a natural oxide layer on a surface of the protruding part 155 of the first semiconductor device 100 may be prevented or substantially reduced such that a typical flux process is not required. As a result, reliability deterioration of a semiconductor package, which is caused by a typical flux, may be prevented or substantially reduced, thereby improving its productivity.

In exemplary embodiments, when the protruding part 155 of the first semiconductor device 100 is bonded to the internal terminal 305 of the package substrate 300, a heat of a first specific temperature may be supplied. Therefore, the protruding part 155 may be mounted in the internal terminal 305 formed of a low melting point conductive material. That is, the relatively hard protruding part 155 may be mounted in the relatively soft inner terminal 305. In exemplary embodiments, the first specific temperature may be lower than a melting point of a surface of the protruding part 155. As a result, the protruding part 155 and the internal terminal 305 may be eutectically bonded to each other. That is, in an exemplary embodiment, atoms around a surface of the protruding part 155 may be mixed with atoms of the internal terminal 305 at an interface between the protruding part 155 and the internal terminal 305. Therefore, even if the internal terminal 305 has a weak tolerance with respect to the oxidation, the protruding part 155 and the internal terminal 305 may still be electrically connected to each other.

In exemplary embodiments, the second semiconductor device 100′ may be combined on the inactive surface 103 of the first semiconductor device 100. The second semiconductor device 100′ may include a protruding type terminal 150′. In exemplary embodiments, the protruding type terminal 150′ of the second semiconductor device 100′ may be mounted into the mounting region of the through electrode 150 of the first semiconductor device 100. In exemplary embodiments, at least one surface of the protruding type terminal 150′ of the second semiconductor device 100′ may be formed of an oxidation resistance-conductive material. Additionally, in further exemplary embodiments, at least one surface of the protruding type terminal 150′ may be formed of a conductive material having a higher melting point than that of the internal pattern 145 in the through electrode 150 of the first semiconductor device 100. In an exemplary embodiment, at least one surface of the protruding type terminal 150′ may be formed of a precious metal. However, the present general inventive concept is not limited thereto.

In exemplary embodiments, since at least one surface of the protruding type terminal 150′ may be formed of an oxidation resistance-conductive material, a typical flux process is not required when the second semiconductor device 100′ is mounted on the inactive surface 103 of the first semiconductor device 100. Accordingly, reliability deterioration of a semiconductor package may be prevented or substantially reduced, and also its productivity may be improved.

In exemplary embodiments, when the protruding type terminal 150′ is combined with the through electrode 150, a heat of a second specific temperature may be supplied. Since at least one surface of the protruding type terminal 150′ has a higher melting point than that of the internal pattern 145 of the through electrode 150 of the first semiconductor device 100, the protruding type terminal 150′ may be mounted in the through electrode 150 (i.e., in the first via hole 120 of the first semiconductor device 100). As a result, reliability deterioration due to a coupling between the first and second semiconductor devices 100 and 100′ may be prevented or substantially reduced. In exemplary embodiments, the second specific temperature may be lower than a melting point of at least one surface of the protruding type terminal 150′. Similar to the protruding part 155 and the internal terminal 305 of the first semiconductor device 100, the protruding type terminal 150′ of the second semiconductor device 100′ and the through electrode 150 of the first semiconductor device 100 may be eutectically bonded to each other. However, the present general inventive concept is not limited thereto.

As illustrated in FIG. 5, the protruding type terminal 150′ of the second semiconductor device 100′ may have a same or substantially similar form as the through electrode 150 of the first semiconductor device 100. That is, in exemplary embodiments, the protruding type terminal 150′ of the second semiconductor device 100′ may penetrate through the semiconductor substrate, the device insulation layer 105′, and the pad 110′ of the second semiconductor device 100′, and may include a protruding part 155′ which protrudes from the pad 110′. In the present exemplary embodiment, the protruding part 155′ of the protruding type terminal 150′ may be mounted into the through electrode 150 of the first semiconductor device 100. In exemplary embodiments, portions of the first and second semiconductor devices 100 and 100′, which need to be insulated from each other, may be insulated by at least one of the protective insulation layer 115′ of the second semiconductor device 100′ and the barrier insulation layer 125 on the inactive surface 103 of the first semiconductor device 100. However, the present general inventive concept is not limited thereto.

According to an exemplary embodiment of the present general inventive concept, the protruding type terminal 150′ of the second semiconductor device 100′ may include various other forms. That is, the protruding type terminal 150′ of the second semiconductor device 100′ may be one of the through electrodes 150a, 150b, and 150c of FIGS. 2 through 4. According to the present exemplary embodiment of the present general inventive concept, the first semiconductor device 100 may be replaced with one of the semiconductor devices 100a, 100b, and 100c of FIGS. 2 through 4.

According to an exemplary embodiment of the present general inventive concept, a third semiconductor device may be interposed between the first semiconductor device 100 and the package substrate 300. In exemplary embodiments, the third semiconductor device may be one of the semiconductor devices 100, 100a, 100b, and 100c of FIGS. 1 through 4. In the present exemplary embodiment, the protruding part 155 of the first semiconductor device 100 may be mounted in a mounting region (i.e., a first via hole) of the through electrode in the third semiconductor device. However, the present general inventive concept is not limited thereto.

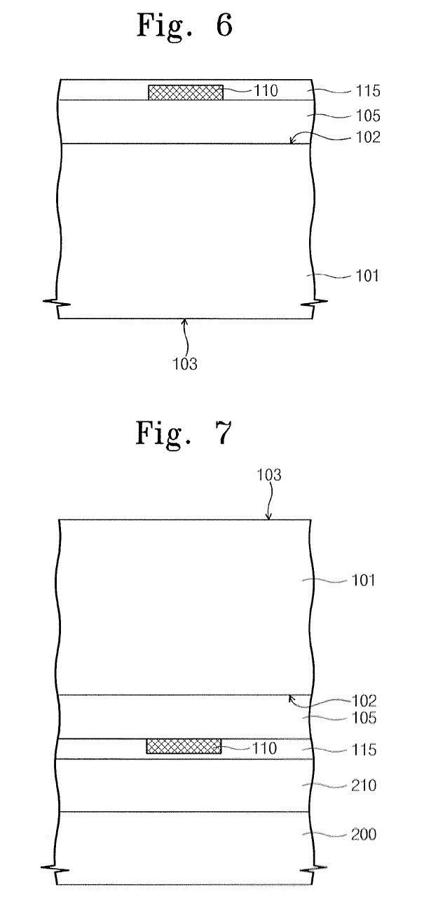

FIGS. 6 through 12 are schematic cross-sectional views which illustrate a method of fabricating a semiconductor device according to exemplary embodiments of the present general inventive concept.

Referring to FIG. 6, in exemplary embodiments, a device insulation layer 105 may be formed on an active surface 102 of a semiconductor substrate 101. The semiconductor substrate 101 may include an inactive surface 103 which faces the active surface 102. In exemplary embodiments, forming the device isolation layer 105 may include forming semiconductor components (e.g., a logic circuit, a peripheral circuit, or a memory cells) that a semiconductor devices requires on the active surface 102 and in the device isolation layer 105 of the semiconductor substrate 101. In exemplary embodiments, a pad 110 may be formed on the device isolation layer 105. The pad 110 may be electrically connected to the semiconductor components. In exemplary embodiments, a protective insulation layer 115 may be formed to cover the device isolation layer 105 and the pad 110. After the forming of the protective insulation layer 115, an opening part may be formed to expose the pad 110 by patterning the protective insulation layer 115. However, in alternative exemplary embodiments, the forming of the opening part in the protective insulation layer 115 may be omitted.

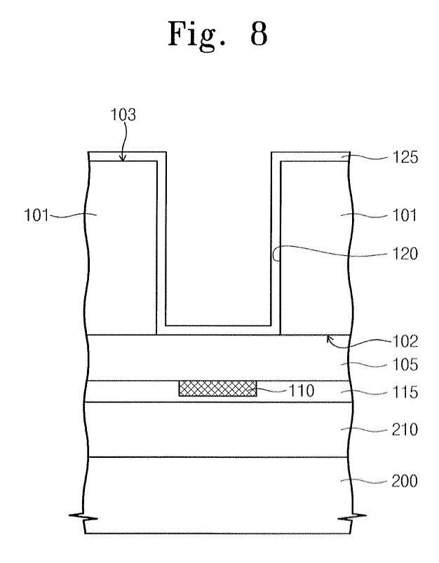

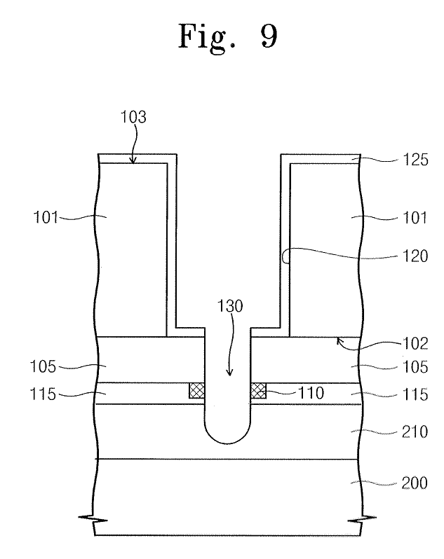

Referring to FIG. 7, a semiconductor structure is bonded with a support substrate 200. The semiconductor structure includes a device insulation layer 105, a pad 110, and a protective insulation layer 115, which may be stacked or sequentially stacked on the semiconductor substrate 101 and on the active surface 102. In exemplary embodiments, the semiconductor structure may be bonded with the support substrate 200 through a substrate adhesive layer 210. More specifically, the substrate adhesive layer 210 may be formed on the protective insulation layer 115, and the support substrate 200 may be bonded on the substrate adhesive layer 210. In exemplary embodiments, the substrate adhesive layer 210 may be in a tape form and may respond to a heat or an ultraviolet light. To be more specific, the substrate adhesive layer 210 may be a tape whose adhesiveness may be deteriorated through heat or ultraviolet light. In exemplary embodiments, the support substrate 200 may be a transparent substrate which transmits or emits light. During a subsequent process, the support substrate 200 may support the semiconductor structure including the semiconductor substrate 101, the device insulation layer 105 and the pad 110. During the subsequent process, the bonding structure (i.e., a structure including the semiconductor structure, the substrate adhesive layer 210, and the support substrate 200) may be treated as the inactive surface 103 of the semiconductor substrate 101 faces the top, with respect to FIG. 7.

Referring to FIG. 8, in exemplary embodiments, the semiconductor substrate 101 may be patterned in a direction from the inactive surface 103 toward the active surface 102, in order to form a first via hole 120 and expose the device isolation layer 105. In exemplary embodiments, the first via hole 120 may penetrate through the semiconductor substrate 101. In exemplary embodiments, the first via hole 120 may be formed on the pad 110. During the patterning of the first via hole 120, the first via hole 120 and the pad 110 may be aligned through a dual side aligning method. However, the present general inventive concept is not limited thereto. During the forming of the first via hole 120, the device insulation layer 105 may be used as an etch stop layer. To be more specific, during the forming of the first via hole 120, a gate insulation layer or an ion implantation buffer insulation layer in the device insulation layer 105, or an oxide layer formed during a gate oxidation process may be used as an etch stop layer.

In exemplary embodiments, a barrier insulation layer 125 may be conformally formed on the bonding structure having the first via hole 120. As a result, the barrier insulation layer 125 may be conformally formed on a sidewall of the first via hole 120, the device insulation layer 102 exposed by the first via hole 120, and the inactive surface 103. However, the present general inventive concept is not limited thereto. That is, the barrier insulation layer 125 may be formed to correspond with various other shapes of the first via hole 120. In exemplary embodiments, the barrier insulation layer 125 may be formed through a chemical vapor deposition (CVD) method, a pulsed deposition method, or a polymer spraying method. In exemplary embodiments, the barrier insulation layer 12 may be formed of at least one of an oxide layer, a nitride layer, and polymer. However, the present general inventive concept is not limited thereto. That is, the barrier insulation layer 12 may be formed by any other desired method or material known in the art.

Referring to FIG. 9, in exemplary embodiments, a second via hole 130 may be formed by continuously etching the barrier insulation layer 125, the device isolation layer 105, the pad 110, the protective insulation layer 115, and the substrate adhesive layer 210 in the first via hole 120. In exemplary embodiments, the second via hole 130 may penetrate the barrier insulation layer 125, the device insulation layer 105, the pad 110, and the protective insulation layer 115, and may also extend toward a bottom surface which is to be formed in the substrate adhesive layer 210. In exemplary embodiments, the second via hole 130 may penetrate the pad 110 to thereby expose a side of the pad 110. In a subsequent process, the protruding parts 155 and 155a of FIGS. 1 through 4 may be formed in the second via hole 130 within the substrate adhesive layer 210.

In exemplary embodiments, the second via hole 130 may be formed through a patterning process which may include an exposure process for defining the second via hole 130. However, in alternative exemplary embodiments, the second via hole 130 may be formed through a laser drilling process. In further exemplary embodiments, if an opening part for exposing the pad 110 is formed on the protective insulation layer 115, the protective insulation layer 115 may not be etched during the formation of the second via hole 130.

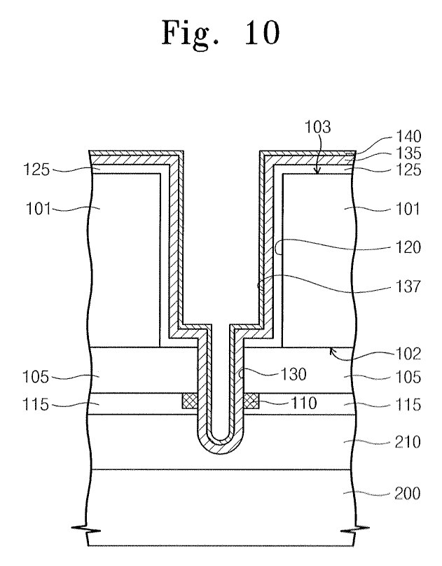

Referring to FIG. 10, in exemplary embodiments, an external conductive layer 135 may be conformally formed on a bonding structure having the second via hole 130. The external conductive layer 135 which may be formed in the first and second via holes 120 and 130 may define a concave region 137 having an open entrance at the inactive surface 103. That is, the concave region 137 may correspond to a space surrounded by the external conductive layer 135 formed in the first and second via holes 120 and 130. As illustrated in the drawings, the external conductive layer 135 may fill a portion of the second via hole 130 and a portion of the first via hole 120. Accordingly, the concave region 137 may be disposed in the first and second via holes 120 and 130. In exemplary embodiments, the concave region 137 may be formed in a portion of the second via hole 130 which is formed in the substrate adhesive layer 210. In further exemplary embodiments, the external conductive layer 135 may be formed of an oxidation resistance-conductive material. The external conductive layer 135 may be formed through a CVD method, a sputtering method, or an E-beam evaporating method. However, the present general inventive concept is not limited thereto.

In exemplary embodiments, an interlayer conductive layer 140 may be conformally formed on the external conductive layer 135. The interlayer conductive layer 140 may include at least one of an adhesive conductive material and a barrier conductive material. In exemplary embodiments, the adhesive conductive material may be one material selected from titanium, tantalum, and nickel. In further exemplary embodiments, the barrier conductive material may be a conductive metal nitride (e.g., nitride titanium, or nitride tantalum). However, the present general inventive concept is not limited thereto.

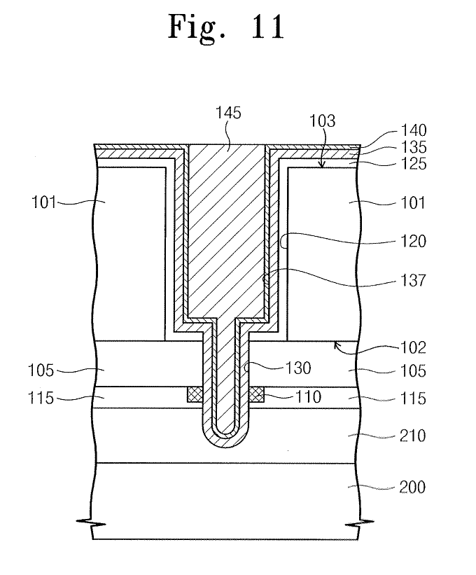

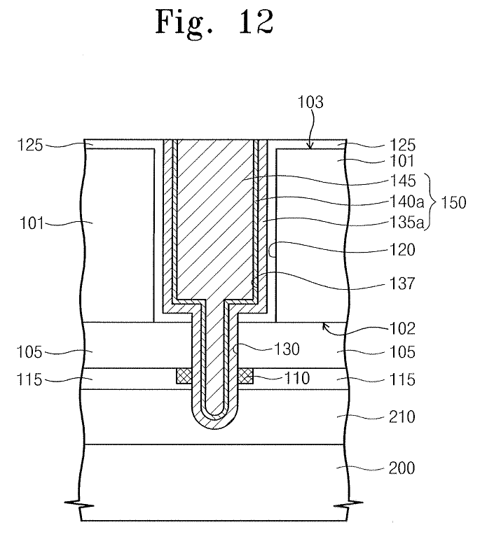

Referring to FIG. 11, in exemplary embodiments, an internal pattern 145 may be formed to fill the first and second via holes 120 and 130. In further exemplary embodiments, the internal pattern 145 may be formed of a low melting point conductive material having a lower melting point than that of the external conductive layer 135. In yet further exemplary embodiments, the external conductive layer 135 may be formed of an oxidation resistance-conductive material having a higher oxidation resistance than that of the internal pattern 145. In an exemplary embodiment, the external conductive layer 135 may be formed of a precious metal, and the internal pattern 145 may be formed of solder or tin. However, the present general inventive concept is not limited thereto. That is, the external layer 135 and the internal pattern 145 may be formed of any other desired materials known in the art.

In exemplary embodiments, a method of forming the internal pattern 145 includes a CVD method, a physical vapor deposition (PVD) method, a plating method, a solder injection method, or a screen printing method. However, the present general inventive concept is not limited thereto.

Description of an exemplary embodiment of a method of forming the internal pattern 145 includes a CVD method, a PVD method, or a plating method will be made in more detail. In an exemplary embodiment, an internal conductive layer may be formed through a CVD method, a PVD method, or a plating method. In the present exemplary embodiment, the internal conductive layer may fill the first and second via holes 120 and 130, and may be formed on the inactive surface 103. The interlayer conductive layer 140 which is disposed on the inactive surface 103 may be removed through a planarization process to form the internal pattern 145. In exemplary embodiments, the planarization process may be performed through a chemical mechanical polishing (CMP) process or a blanket anisotropic etching process. However, the present exemplary embodiment is not limited thereto.

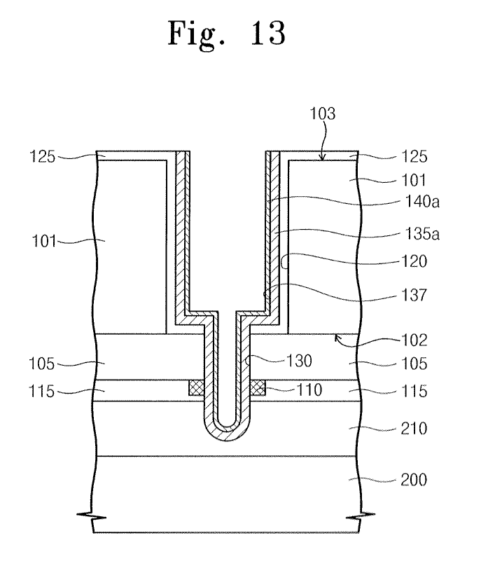

On the other hand, in alternative exemplary embodiments, the internal conductive layer may be conformally formed. That is, the internal conductive layer may be formed to fill the second via hole 130 and a portion of the first via hole 120. In the present exemplary embodiment, the semiconductor device 100a of FIG. 2 may be realized by performing a subsequent process, which will be described below with reference to FIG. 12.

In exemplary embodiments, if the internal pattern 145 is formed through a solder injection method or a screen printing method, the internal pattern 145 may be formed being limited to an internal region of the first and second via holes 120 and 130. In the present exemplary embodiment, the planarization process may be omitted.

Referring to FIGS. 11 and 12, by removing the interlayer conductive layer 140 and the external conductive layer 135 disposed on the inactive surface 103, an external pattern 135a and an interlayer conductive pattern 140a may be formed in the first and second via holes 120 and 130. The external pattern 135a and the interlayer conductive pattern 140a surround the internal pattern 145. In exemplary embodiments, the external pattern 135a, the interlayer conductive pattern 140a, and the internal pattern 145 may constitute a through electrode 150.

Next, the substrate adhesive layer 210 and the support substrate 200 are separated from the protective insulation layer 115. In the current exemplary embodiment, a portion (that is, the protruding part 155 of FIG. 1) of the through electrode 150 filling the second via hole 130 in the substrate adhesive layer 210 may be exposed to an external environment. Therefore, the semiconductor device 100 of FIG. 1 may be realized.

In exemplary embodiments, the substrate adhesive layer 210 and the support substrate 200 may be separated from the bonding structure including the through electrode 150 by supplying heat or ultraviolet light to the substrate adhesive layer 210. In exemplary embodiments, when ultraviolet light is supplied to the substrate adhesive layer 210, the ultraviolet light may be supplied through a transparent support substrate 200.

In exemplary embodiments, if the semiconductor substrate 101 is a wafer which includes a plurality of semiconductor devices, after separating the substrate adhesive layer 210 and the support substrate 200, each semiconductor device may be distinguished by sawing the wafer. Unlike this, in alternative exemplary embodiments, the semiconductor substrate 101 may be included or integrated into one semiconductor device.

According to the above-mentioned exemplary embodiment of a method of fabricating a semiconductor device, the first via hole 120 may be formed by performing an etching process from the inactive surface 103 toward the active surface 102. Accordingly, the active surface 102, the device isolation layer 105, and the pad 110 may be protected from fragments of the semiconductor substrate 101 that may generated during the etching of the first via hole 120. In an exemplary embodiment, the active surface 102, the device isolation layer 105, and the pad 110 may be protected by the substrate adhesive layer 210 and the support substrate 200. Consequently, reliability deterioration of a semiconductor device, which is caused by fragments of the semiconductor substrate 101, may be prevented or substantially reduced.

The exemplary embodiment of a method for fabricating a semiconductor device is partially modified to form the semiconductor devices 100a, 100b, and 100c of FIGS. 2 through 4. As mentioned above, the internal conductive layer may be formed to fill a portion of the first via hole 120 such that the semiconductor device 100a of FIG. 2 may be realized.

According to the above-mentioned exemplary embodiment of a method of fabricating a semiconductor device, by increasing a thickness of the external conductive layer 135, the external conductive layer 135 may completely fill the second via hole 130 and a portion of the first via hole 120. In the present exemplary embodiment, the semiconductor device 100b of FIG. 3 may be realized.

In exemplary embodiments, the semiconductor device 100c of FIG. 4 may be realized by combining the methods of fabricating the semiconductor device 100b and the semiconductor device 100a. That is, according to the method of fabricating the semiconductor device 100b of FIG. 3, the semiconductor device 100c of FIG. 4 may be realized if the external conductive layer is formed to fill a portion of the first via hole 120.

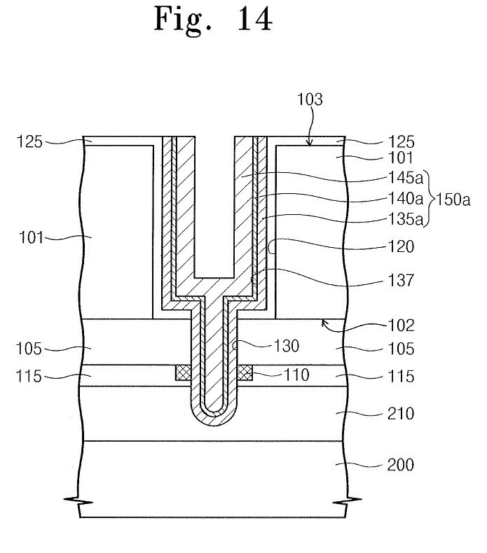

On the other hand, according the above-mentioned exemplary embodiment of a method of fabricating a semiconductor device, the internal pattern 145 may be formed first and then the internal pattern 145a and the interlayer conductive pattern 140a are formed. However, in alternative exemplary embodiments, after the internal pattern 145a and the interlayer conductive pattern 140a are formed first, and then the internal pattern 145 may be formed. This method will now be described in more detail with reference to FIGS. 13 and 14. This method may include the exemplary embodiments of methods described with reference to FIGS. 6 through 10.

FIGS. 13 and 14 are schematic cross-sectional views which illustrate one modification of a method of fabricating a semiconductor device according to exemplary embodiments of the present general inventive concept.

Referring to FIGS. 10 and 13, by removing the interlayer conductive layer 140 and the external conductive layer 135 on the inactive surface 103, an external pattern 135a and an interlayer conductive pattern 140a may be sequentially stacked in the first and second via holes 120 and 130. In the present exemplary embodiment, the barrier insulation layer on the inactive surface 103 may be exposed. In exemplary embodiments, the interlayer conductive layer 140 and the external conductive layer 135 on the inactive surface 103 may be removed by a CMP process. However, the present general inventive concept is not limited thereto. That is, the interlayer conductive layer 140 and the external conductive layer 135 may be removed by various other processes known in the art.

However, in alternative exemplary embodiments, a sacrificial layer (not illustrated) may be formed in the first and second via holes 120 and 130, and the interlayer conductive layer 140 and the external conductive layer 135 on the inactive surface 103 may be removed by a blanket anisotropic etching process. However, the present general inventive concept is not limited thereto. That is, the interlayer conductive layer 140 and the external conductive layer 135 may be removed by various other processes known in the art. In exemplary embodiments, the sacrificial layer in the first and second via holes 120 and 130 protects the external pattern 135a and the interlayer conductive pattern 140a from the blanket anisotropic etching process. After forming the external pattern 135a and the interlayer conductive pattern 140a, the sacrificial layer may be removed. Even if the interlayer conductive layer 140 and the external conductive layer 135 on the inactive surface 103 are removed through a CMP process, the sacrificial layer may protect the external pattern 135a and the interlayer conductive pattern 140a.

Referring to FIG. 14, in exemplary embodiments, an internal pattern 140a may be formed in the first and second via holes 120 and 130. As illustrated in the drawings, the internal pattern 140a completely fills the second via hole 130, but fills a portion of the first via hole 120. In the present exemplary embodiment, the semiconductor device 100a of FIG. 2 may be realized. In the present exemplary embodiment, the internal pattern 140a may be formed through a plating method by using the interlayer conductive pattern 140a as a seed layer (if the interlayer conductive pattern 140a is omitted, the external pattern 135a may be used as a seed layer). In exemplary embodiments, the internal pattern 140a may be formed through a PVD method, a CVD method, of a planarization process. However, the present general inventive concept is not limited thereto. That is, the internal pattern 140a may be formed by various other processes known in the art.

However, in alternative exemplary embodiments, if the internal pattern 145 of FIG. 1 is formed on the interlayer conductive pattern 140a to completely fill the first and second via holes 120 and 130, the semiconductor device 100 of FIG. 1 may be realized. At this point, if the internal pattern 145 is formed through a plating method, the interlayer conductive pattern 140a or the external pattern 135a, which is used as a seed layer of the internal pattern 145, may only exist in the first and second via holes 120 and 130, such that the internal pattern 145 may be formed being limited in the first and second via holes 120 and 130.

In exemplary embodiments, if the external pattern 135a is formed to completely fill the second via hole 130, but fills a portion of the first via hole 120, the semiconductor devices 100b and 100c of FIGS. 3 and 4 may be realized by combining the methods of fabricating the internal pattern described with reference to FIG. 14.

The through electrode of the exemplary embodiments described above includes an external pattern formed of an oxidation resistance-conductive material and an internal pattern formed of a low melting point conductive material. However, a semiconductor device according to the present exemplary embodiment includes a through electrode formed only of an oxidation resistance-conductive material. According to the present exemplary embodiment, like reference numerals refer to like elements throughout the previously described exemplary embodiments.

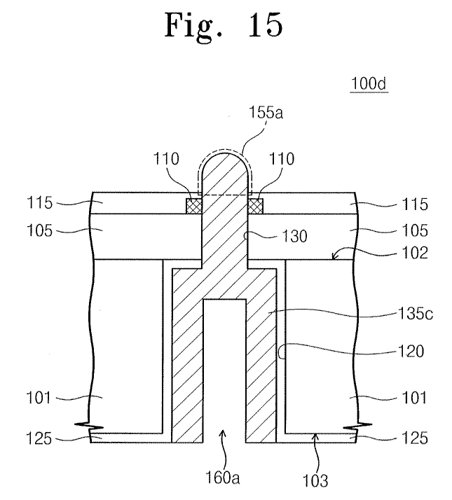

FIG. 15 is a cross-sectional schematic view of a semiconductor device according to another exemplary embodiment of the present general inventive concept.

Referring to FIG. 15, a semiconductor device 100d includes a through electrode 135c formed of an oxidation conductive material. In exemplary embodiments, the through electrode 135c may be formed of the same or substantially similar material as the external patterns 135a and 135b of FIGS. 1 through 4 of the previous exemplary embodiments. In an exemplary embodiment, the through electrode 135c may be formed of a precious metal. However, the present general inventive concept is not limited thereto. That is, in exemplary embodiments, the through electrode 135c may be formed of various other materials known in the art.

In the present exemplary embodiment, the through electrode 135c may be disposed in a first via hole 120 which penetrates a semiconductor substrate 101 and a second via hole 130 which penetrates a device isolation layer 105 and a pad 110. Additionally, the through electrode 135c may include a protruding part 155a that protrudes from the pad 110. In an exemplary embodiment, the protruding part 155a may protrude higher than at least a portion of the pad 110 and a protective insulation layer 115 which covers a device isolation layer 105. The through electrode 135c completely fills the second via hole 130, but fills a portion of the first via hole 120. A portion of the through electrode 135c disposed in the first via hole 120 may extend with a uniform thickness along the sidewall of the first via hole 120. Therefore, a mounting recessed region 160a, which is surrounded by a portion of the through electrode 135c, may be defined in the first via hole 120. At this point, the mounting recessed region 160a may include an open entrance at an inactive surface 103 of the semiconductor substrate 101 and the internal wall of the mounting recessed region 160a may be formed of the through electrode 135c. The through electrode 135c includes an mounting region in the first via hole 120, where a protruding type terminal of another semiconductor device (not illustrated) may be mounted. At this point, the mounting region of the through electrode 135c includes at least a portion of the mounting recessed region 160a and at least a portion of the through electrode 135c that defines the mounting recessed region 160a.

Next, an exemplary embodiment of a method of forming the semiconductor device 100d will now be described in more detail. The present exemplary embodiment includes the method of forming the first and second via holes 120 and 130 described with reference to FIGS. 6 through 9. However, the method of fabricating the semiconductor device 100d does not require a method of forming the interlayer conductive layer 140 and the internal pattern 145 disclosed in the first embodiment. This method will now be described in more detail with reference to FIG. 9.

Referring to FIG. 9, an oxidation resistance-conductive layer is conformally formed on the bonding structure having the first and second via holes 120 and 130. At this point, by adjusting the thickness of the oxidation resistance-conductive layer, the oxidation resistance-conductive layer completely fills the second via hole 130, but fills a portion of the first via hole 120. By removing the oxidation resistance-conductive layer which is formed on the inactive surface 103 of the semiconductor substrate 101, the through electrode 135c of FIG. 15 may be formed in the first and second via holes 120 and 130. Then, the substrate adhesive layer 210 and the support substrate 200 may be separated from the bonding structure, such that the semiconductor device 100d of FIG. 15 may be realized.

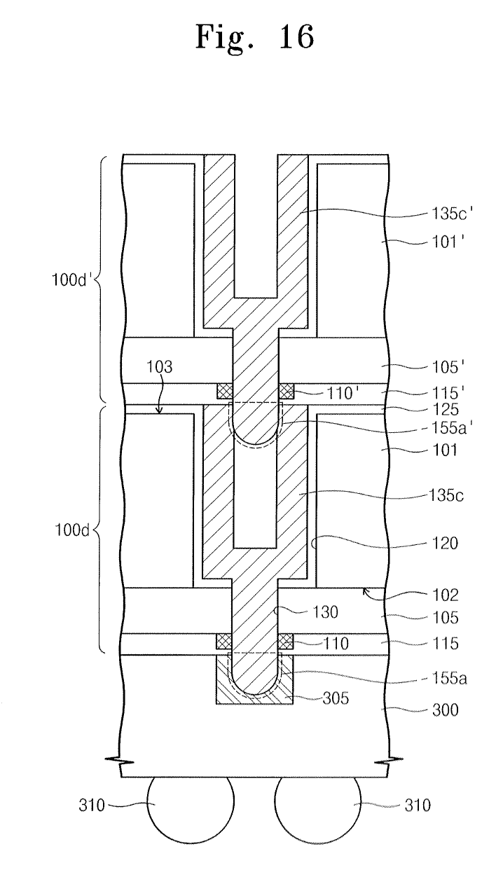

FIG. 16 is a cross-sectional schematic view of a semiconductor package including a semiconductor device according to another exemplary embodiment of the present general inventive concept.

Referring to FIG. 16, a semiconductor package includes a package substrate 300 and at least one of semiconductor devices 100d and 100d′ stacked on the package substrate 300. The semiconductor package of FIG. 16 includes a first semiconductor device 100d and a second semiconductor device 100d′, which are sequentially stacked on the package substrate 300. However, in alternative exemplary embodiments, the second semiconductor device 100d may be omitted. In addition, in further alternative exemplary embodiments, a third semiconductor device may be disposed between the first semiconductor device 100d and the package substrate 300 or on the second semiconductor device 100d′.

In exemplary embodiments, a protruding part 155a of the through electrode 135c in the first semiconductor device 100d may be combined with an internal terminal 305 of the package substrate 300. At this point, the internal terminal 305 of the package substrate 300 may be formed of a low melting point conductive material having a lower melting point than that of the through electrode 135c. Therefore, the protruding part 155a of the through electrode 135c may be mounted in the internal terminal 305. The protruding part 155a of the through electrode 135c and the internal terminal 305 may be eutectically bonded to each other. Since the eutectic bonding has been described above with reference to FIG. 5, an overlapping description thereof will be omitted.

The second semiconductor device 100d′ includes a protruding type terminal 135c′. In exemplary embodiments, at least one surface of the protruding type terminal 135c′ may be formed of an oxidation resistance-conductive material. The protruding type device 135c′ of the second semiconductor device 100d′ may be mounted in a mounting recessed region of the through electrode 135c of the first semiconductor device 100d. In exemplary embodiments, the width of the mounting recessed region of the through electrode 135c may be identical to or less than that of the protruding portion 155a′ of the protruding type terminal 135c′. Therefore, the protruding part 155a′ of the protruding type terminal 135c′ may contact the through electrode 135c.

When the protruding type terminal 135c′ of the second semiconductor device 100d′ is bonded with the through electrode 135c of the first semiconductor device 100d, a heat of a specific temperature may be supplied. Therefore, even if the width of the protruding part 155a′ of the protruding type terminal 135c′ is equal to or less than that of the mounding depressed part of the through electrode 135c, the protruding part 155a′ of the protruding type terminal 135c′ may still be electrically mounted in the mounting recessed region. The protruding part 155a′ of the protruding type terminal 135c′ and the through electrode 135c may be eutectically bonded to each other.

In exemplary embodiments, the through electrode 135c may be formed of an oxidation resistance-conductive material. Therefore, forming of a natural oxide layer on the interface between the protruding part 155a′ and the through electrode 135c may be prevented or substantially reduced. Accordingly, reliability deterioration of a semiconductor package, caused due to a typical flux process, may be prevented or substantially reduced. Moreover, the productivity of a semiconductor package may be improved.

Furthermore, the surface of the protruding type terminal 135c′ of the second semiconductor device 100d′ is formed of an oxidation resistance-conductive material. Therefore, when the second semiconductor device 100d′ is mounted on the inactive surface 103 of the first semiconductor device 100d, a typical flux process is not required. As a result, the reliability deterioration of a semiconductor package may be prevented and its productivity may be improved.

As illustrated in FIG. 16, the protruding type terminal 135c′ of the second semiconductor device 100d′ may have the same or substantially similar structure as the through electrode 135c of the first semiconductor device 100d. That is, the protruding type terminal 135c′ fills a first via hole penetrating the semiconductor substrate 101′ of the second semiconductor device 100d′ and a second via hole penetrating the device isolation layer 105′ and the pad 110′ of the second semiconductor device 100d′. Additionally, the protruding type terminal 135c′ includes a portion 155a′ that protrudes from the pad 110′ of the second semiconductor device 100d′. By the protective layer 115′ of the second semiconductor device 100d′ and/or the barrier insulation layer 125 on the inactive surface 103 of the first semiconductor device 100d, portions that need to be insulated between the first and second semiconductor devices 100d and 100d′ may be insulated.

On the other hand, the protruding type device 135c′ of the second semiconductor device 100d′ may be replaced with any one among the through electrodes 150, 150a, 150b, and 150c of FIGS. 1 through 4. As mentioned above, a third semiconductor device may be disposed on the second semiconductor device 100d′ or between the first semiconductor device 100d and the package substrate 300. At this point, the third semiconductor device may be one of the semiconductor devices 100, 100a, 100b, and 100c of FIGS. 1 through 4.

As mentioned above, according to the present invention, at least the surface of a protruding part of a through electrode is formed of an oxidation resistance-conductive material. Accordingly, a flux process for cleaning a typical natural oxide layer is not required. Therefore, the reliability deterioration of a semiconductor package including the above-mentioned semiconductor device may be prevented or substantially reduced. Additionally, the productivity of a semiconductor package may be improved.

Additionally, according to the present general inventive concept, a semiconductor substrate is patterned from an inactive surface to an active surface in order to form a first via hole. Accordingly, during the forming of the via hole, a pad may be protected from an etching residue (e.g., fragments of a semiconductor substrate). Therefore, the reliability deterioration of a semiconductor device, which is caused due to an etching residue during the forming of a first via hole, can be prevented or substantially reduced.

The above-disclosed subject matter is to be considered illustrative, and not restrictive, and the appended claims are intended to cover all such modifications, enhancements, and other exemplary embodiments, which fall within the true spirit and scope of the present general inventive concept. Thus, to the maximum extent allowed by law, the scope of the present general inventive concept is to be determined by the broadest permissible interpretation of the following claims and their equivalents, and shall not be restricted or limited by the foregoing detailed description.

Although a few exemplary embodiments of the present general inventive concept have been shown and described, it will be appreciated by those skilled in the art that changes may be made in these exemplary embodiments without departing from the principles and spirit of the general inventive concept, the scope of which is defined in the appended claims and their equivalents.

1. A semiconductor device comprising:
a semiconductor substrate including an active surface and an inactive surface which faces the active surface;
a device isolation layer and a pad stacked on the active surface; and
a through electrode disposed in a first via hole and in a second via hole, the through electrode including a protruding part that protrudes from the pad, the first via hole penetrates the semiconductor substrate, the second via hole penetrates the device insulation layer and the pad,
wherein at least a surface of the protruding part of the through electrode is formed of an oxidation resistance-conductive material.

2. The semiconductor device of claim 1, wherein the through electrode comprises:
an external pattern formed of the oxidation resistance-conductive material; and
an internal pattern disposed in a concave region defined by the external pattern,
wherein the concave region has an open entrance at the inactive surface and the oxidation resistance-conductive material has a higher oxidation resistance than that of the internal pattern.

3. The semiconductor device of claim 2, wherein the internal pattern is formed of a low melting point conductive material having a lower melting point than that of the external pattern.

4. The semiconductor device of claim 2, wherein the concave region is defined in the first and second via holes and the protruding part.

5. The semiconductor device of claim 4, wherein the internal pattern fills the concave region.

6. The semiconductor device of claim 4, wherein the internal pattern fills the concave region in the protruding part and the second via hole and corresponds to a profile of the concave region in the first via hole.

7. The semiconductor device of claim 2, wherein the protruding part is formed of the external pattern, the external pattern fills the second via hole, and the concave region is defined in the first via hole.

8. The semiconductor device of claim 7, wherein the internal pattern fills the concave region.

9. The semiconductor device of claim 7, wherein the internal pattern corresponds to a profile of the concave region.

10. The semiconductor device of claim 2, wherein the through electrode further comprises an interlayer conductive pattern disposed between the internal pattern and the external pattern, the interlayer conductive pattern including at least one of an adhesive conductive material and a barrier conductive material.

11. The semiconductor device of claim 1, wherein the through electrode is formed of the oxidation resistance-conductive material, fills the second via hole, and corresponds to a profile of the first via hole, to thereby define a mounting recessed region which is surrounded by the through electrode in the first via hole.

12. The semiconductor device of claim 11, wherein the oxidation resistance-conductive material is formed of a precious metal.

13. The semiconductor device of claim 1, wherein the through electrode comprises a mounting region in the first via hole, where a protruding type terminal of another semiconductor device is capable of being mounted.

14. The semiconductor device of claim 1, further comprising a barrier insulation layer between a sidewall of the first via hole and the through electrode.

15. The semiconductor device of claim 1, wherein a width of the protruding part is equal to or less than that of the first via hole.

16-21. (canceled)
